(19) United States
(12) Patent Application Publication
(10) Pub. No.: US 2007/0042224 A1
(43) Pub. Date: Feb. 22, 2007

(54) Process for producing thin hafnium or zirconium nitride coatings

(75) Inventors: Knud Reuter, Krefeld (DE); Gerd Passing, Hurth (DE); Younsoo Kim, Yongin-City (KR); Harish Parala, Bochum (DE); Roland A. Fischer, Bochum (DE)

Correspondence Address: CONNOLLY BOVE LODGE & HUTZ, LLP, P O BOX 2207, WILMINGTON, DE, 19899, US

(73) Assignee: H.C. Starck GmbH, Goslar (DE)

(21) Appl. No.: 11/482,385

(22) Filed: Jul. 7, 2006

(30) Foreign Application Priority Data
Jul. 19, 2005 (DE) 10 2005 033 579.9

(51) Int. Cl. C23C 16/00; B32B 9/00

(52) U.S. Cl. 428/698; 427/248.1

(57) ABSTRACT

A process for producing hafnium(III) nitride (HfN) or zirconium nitride coatings by means of the CVD method (chemical vapour deposition) from a reactive gas on a substrate surface, the HfN coating or ZrN coating and their use are described. In the process, a hafnium or zirconium tetrakis(dialkylamide) having the general formula
Hf(NR¹R²)₄ or Zr(NR¹R²)₄
wherein R¹ and R² denote identical or different, straight-chain or branched C₁ to C₄ alkyl radicals, is used as the Hf precursor or Zr precursor and a hydrazine derivative having the general formula
H₂N—NR³R⁴
wherein R³ denotes a straight-chain or branched C₁ to C₄ alkyl radical and R⁴ independently denotes a C₁ to C₄ alkyl radical or H, is used as the reactive gas.

### CROSS-REFERENCE TO RELATED APPLICATION

This application claims priority under 35 U.S.C. §119 (a-e) to German application DE 10 2005 033 579, filed Jul. 19, 2005.

### FIELD OF THE INVENTION

The present invention concerns a process for producing thin hafnium nitride (HfN) or zirconium nitride (ZrN) coatings using the metalorganic chemical vapour deposition method (MOCVD).

### BACKGROUND OF THE INVENTION

Due to the ever-decreasing size of microelectronic components, down to <100 nm, it is becoming increasingly important to be able to obtain components with an adequate electrical capacity. Silicon dioxide (SiO₂) and so-called poly-silicon (p-Si) have been used until now as a dielectric or electrode material for micro-electronic components. This combination exhibits excellent physical, in particular electrical, properties, since both materials are based on Si. Whilst the latest research shows that hafnium oxide above all has a very high dielectric constant k, interest has finally focused more particularly on hafnium nitride (HfN) because of its novel combination of properties comprising high dielectric constant and suitability as an electrode material. HfN has also been used as a diffusion barrier and coating material because of its good electrical conductivity, its high melting point and its high hardness and density values (see S. Shinkai and K. Sasaki, Jpn. J. Appl. Phys., 38, 3646 (1999)). HfN is also noteworthy for barrier coatings (diffusion barrier due to the great similarity of its crystal lattice to gallium nitride (GaN) (see A. Parkhomovsky, B. E. Ishaug, A. M. Dabiran and P. I. Cohen, J. Vac. Sci. Technol. A, 17, 2162 (1999)).

HfN coatings have been produced until now by the PVD method (physical vapour deposition). Liao et al. reported on the growth of HfN films by direct-current atomisation (DC sputtering; see M. Y. Liao, Y. Gotoh, H. Tsuji, and J. Ishikawa, J. Vac. Sci. Technol. A, 22, 214 (2004)). Due to poor adhesion, however, HfN films deposited by PVD generally exhibit an inherently mediocre step coverage of the substrate, on the basis of which its future applications in microelectronics appear to be limited. Hoffman et al. tried to deposit MN films (M=Zr, Hf) by the MOCVD method (metal organic chemical vapour deposition) (see D. M. Hoffman, Polyhedron, 13, 1169 (1994) and R. Fix, R. G. Gordon and D. M. Hoffman, Chem. Mater., 3, 1138 (1991)). However, only electrically non-conductive M₃N₄ coatings (M=Zr, Hf) were produced in these studies, since for Hf and Zr the oxidation stage +4 is by far the most stable oxidation stage. Until now, it has apparently not been possible to produce conductive ZrN and HfN coatings by means of chemical gas phase deposition.

### SUMMARY OF THE INVENTION

The object of the invention was to produce hafnium nitride or zirconium nitride coatings by means of a novel process which does not have the disadvantages of the prior art.

In the present invention, hafnium or zirconium tetrakis(dialkylamide)s, Hf(NR¹R²)₄ or Zr(NR¹R²)₄ (wherein R¹, R² denote Me, Et in particular), are used as precursor compounds (also referred to below as precursors) and methylhydrazine (MHy, MeHNNH₂) and/or N,N-dimethylhydrazine (DMHy, Me₂NNH₂) is used as the reactive gas.

The invention provides a process for producing hafnium(III) nitride (HfN) or zirconium nitride (ZrN) coatings by means of the CVD method (chemical vapour deposition) from a reactive gas on a substrate surface, characterised in that a hafnium or zirconium tetrakis(dialkylamide) having the general formula
Hf(NR¹R²)₄ or Zr(NR¹R²)₄
wherein R¹ and R² denote identical or different, straight-chain or branched C₁ to C₄ alkyl radicals, is used as the Hf precursor or Zr precursor and a hydrazine derivative having the general formula
   H₂N—NR³R⁴
wherein R³ denotes a straight-chain or branched C₁ to C₄ alkyl radical and R⁴ independently denotes a C₁ to C₄ alkyl radical or H,
   is used as the reactive gas.

### DETAILED DESCRIPTION OF THE INVENTION

As used herein in the specification and claims, including as used in the examples and unless otherwise expressly specified, all numbers may be read as if prefaced by the word “about”, even if the term does not expressly appear. Also, any numerical range recited herein is intended to include all sub-ranges subsumed therein.

On the basis of our current understanding, the reaction of the Hf precursor or Zr precursor and the hydrazine derivative during MOCVD proceeds along the following general lines: The hydrazine derivative reacts with the precursor on the substrate surface to produce HfN and volatile byproducts, such as HNRR′, HNMe₂ or H₂NMe, and N₂. When the volatile byproducts are removed from the reaction chamber, using a vacuum pump for example, the highly crystalline thin HfN coating is formed. The reaction schemes for the Hf coating are, for example:
Hf(NRR′)₄+4 Me₂NNH₂→HfN+4 HNRR′+4 HNMe₂+3/2 N₂, (5)
Hf(NRR′)₄+4 MeHNNH₂→HfN+4 HNRR′+4 H₂NMe+3/2 N₂, (6)
R,R′═Me, Et

A process is preferred in which hafnium or zirconium tetrakis(dimethylamide), hafnium or zirconium tetrakis(methylethylamide) or hafnium or zirconium tetrakis(diethylamide) are used as the hafnium or zirconium compound (precursor).

A process is also preferred in which asymmetrical methylhydrazine and/or asymmetrical dimethylhydrazine (N,N-dimethylhydrazine) are used as a component in the reactive gas.

A process is preferred in which the substrate is heated to a temperature of 200 to 1100° C. during the reaction, particularly preferably to a temperature of 250 to 1000° C.

Advantageously, the reaction is preferably performed under a pressure of 10⁻³ to 10 mbar, particularly preferably 10⁻² to 1 mbar.

To improve coating adhesion, the substrate surface is cleaned before the reaction, in particular by reductive removal of any oxide coatings.

Semiconductors or structured semiconductors, in particular those based on Si, Ge, GaAs, GaN or SiC, are preferably used as substrates in the novel process.

The invention also provides an HfN or ZrN coating produced by the process according to the invention and a substrate exhibiting such an HfN or ZrN coating.

The novel HfN or ZrN coatings can be used as a gate metal in semiconductor structures, in particular in integrated circuits, or as an electrically conductive coating in electronic components, in particular in capacitors or integrated circuits.

A further use of the novel HfN or ZrN coatings lies in the surface hardening of metals, in particular for tool surfaces.

The invention is further illustrated but is not intended to be limited by the following examples in which all parts and percentages are by weight unless otherwise specified

### EXAMPLES

General process: A vertical CVD reactor was used to deposit a thin HfN coating. The reaction chamber in the reactor was evacuated using a rotary slide-valve pump and a turbomolecular pump. The Hf precursor and the reactive additive (DMHy or MHy) were introduced into different washing bottles. The washing bottle with the Hf precursor was heated to a constant temperature with a water heating jacket. The washing bottle inlet and outlet were connected to the carrier gas line and the CVD reactor respectively. The carrier gas stream was controlled automatically with a flow meter. The precursor with the carrier gas and the reactive component was passed vertically through a ¼ inch steel tube onto the 1.0×2.0 cm² substrate. All connections between the washing bottle and the reactor chamber were heated to 110° C. The substrate surfaces were cleaned by a method described in Lit. A. Ishizaka and Y. Shiraki, J. Electrochem. Soc., 133, 666 (1986) and introduced into the reaction chamber. The substrate temperature was checked with a thermocouple and set to the desired value between 200 and 1000° C.

### CVD Example 1

Hf(NMe₂)₄ and DMHy were introduced into the washing bottle in a glove box. The pressure in the reaction chamber was 8.0×10⁻⁵ mbar. To remove the original silicon oxide coating, the substrate was heated to 950° C. for approximately 30 minutes under hydrogen gas before the deposition process. After removal of the oxide coating, HfN deposition was performed at 800° C. for 70 minutes in the reaction chamber. During the deposition, the washing bottles were opened to the chamber and heated to 23° C. A nitrogen carrier gas stream of 20 sccm was passed through the washing bottle with the Hf precursor; the pressure in the reaction chamber during the reaction was 0.1 mbar.

An HfN film having good adhesion was deposited on the Si substrate. The film thickness was 2 μm, the rate of deposition was 29 nm/min. The specific electrical resistance of the coating was measured as 7400 μΩcm. X-ray diffractometry and SEM images (scanning electron microscopy) confirm the deposition of a cubic, crystalline HfN coating.

### CVD Example 2

Hf(NMeEt)₄ and DMHy were introduced into the washing bottle in a glove box. The pressure in the reaction chamber was 8.0×10⁻⁵ mbar. To remove the original silicon oxide coating, the substrate was heated to 950° C. for approximately 30 minutes under hydrogen gas before the deposition process. After removal of the oxide coating, HfN deposition was performed at 800° C. for 35 minutes. During the deposition, the washing bottles were opened to the chamber and heated to 23° C. A nitrogen carrier gas stream of 20 sccm was passed through the washing bottle with the Hf precursor; the pressure in the reaction chamber during the reaction was 0.1 mbar.

An HfN film having good adhesion was deposited on the Si substrate. The film thickness was 0.84 μm, the rate of deposition was 24 nm/min. The specific electrical resistance of the coating was measured as 7700 μΩcm. X-ray diffractometry and SEM images (scanning electron microscopy) confirm the deposition of a cubic, crystalline HfN coating.

### CVD Example 3

Zr(NMeEt)₄ and MHy were introduced into the washing bottle in a glove box. The pressure in the reaction chamber was 1.0×10⁻⁵ mbar. To remove the original silicon oxide coating, the substrate was heated to 950° C. for approximately 30 minutes under hydrogen gas before the deposition process. After removal of the oxide coating, ZrN deposition was performed at 800-850° C. for 30 minutes. During the deposition, the washing bottles were opened to the chamber and heated to 23° C. A nitrogen carrier gas stream of 10 sccm was passed through the washing bottle with the Zr precursor; the pressure in the reaction chamber during the reaction was 0.05 mbar.

A ZrN film having good adhesion was deposited on the Si substrate. The specific electrical resistance of the coating was measured as 6000 μΩcm. X-ray diffractometry and SEM images (scanning electron microscopy) confirm the deposition of a cubic, crystalline ZrN coating.

Although the invention has been described in detail in the foregoing for the purpose of illustration, it is to be understood that such detail is solely for that purpose and that variations can be made therein by those skilled in the art without departing from the spirit and scope of the invention except as it may be limited by the claims.

1. Process for producing hafnium(III) nitride (HfN) or zirconium nitride (ZrN) coatings by the CVD method (chemical vapour deposition) from a reactive gas on a substrate surface, the process comprising the step of reacting hafnium or zirconium tetrakis(dialkylamide) having the general formula
Hf(NR¹R²)₄ or Zr(NR¹R²)₄
wherein R¹ and R² denote identical or different, straight-chain or branched C₁ to C₄ alkyl radicals,
with a hydrazine derivative having the general formula
H₂N—NR³R⁴
wherein R³ denotes a straight-chain or branched C₁ to C₄ alkyl radical and R⁴ independently denotes a C₁ to C₄ alkyl radical or H,
on the surface of the substrate to produce hafnium(III) nitride (HfN) or zirconium nitride (ZrN) coatings on the substrate.

2. Process according to claim 1, wherein hafnium tetrakis(dimethylamide), hafnium tetrakis(methylethylamide) or hafnium tetrakis(diethylamide) are used as the hafnium compound.

3. Process according to claim 1, wherein zirconium tetrakis(dimethylamide), zirconium tetrakis(methylethylamide) or zirconium tetrakis(diethylamide) are used as the zirconium compound.

4. Process according to claim 1, wherein asymmetrical methylhydrazine and/or asymmetrical dimethylhydrazine (N,N-dimethylhydrazine) are used as a component in the reactive gas.

5. Process according to claim 1, wherein the substrate is heated to a temperature of 200 to 1100° C. during the reaction.

6. Process according to claim 1, wherein the reaction is performed under a pressure of 10⁻³ to 10 mbar.

7. Process according to claim 1, wherein semiconductors or structured semiconductors based on Si, Ge, GaAs, GaN or SiC are used as substrates.

8. HfN coating produced by a method according to claim 1.

9. ZrN coating produced according to claim 1.

10. An integrated circuit or capacitor having as a gate metal the HfN coating according to claim 8.

11. A metal tool having the HfN coating according to claim 8.

12. Substrate having an HfN coating according to claim 8.

13. An integrated circuit or capacitor having as a gate metal the ZrN coating according to claim 9.

14. A metal tool having the ZrN coating according to claim 9.

15. Substrate having an ZrN coating according to claim 9.
